(19) United States
(12) Patent Application Publication
(10) Pub. No.: US 2026/0324308 A1
(43) Pub. Date: Oct. 15, 2026

(54) GROUP III NITRIDE SEMICONDUCTOR EPITAXIAL WAFER AND DEVICE

(71) Applicant: PANASONIC HOLDINGS CORPORATION, Osaka (JP)

(72) Inventors: Tomoaki SUMI, Osaka (JP); Yusuke MORI, Osaka (JP); Masashi YOSHIMURA, Osaka (JP); Masayuki IMANISHI, Osaka (JP); Shigeyoshi USAMI, Osaka (JP)

(21) Appl. No.: 19/461,116

(22) Filed: Jan. 27, 2026

Related U.S. Application Data
(63) Continuation of application No. PCT/JP2024/005738, filed on Feb. 19, 2024.

(30) Foreign Application Priority Data
Jul. 28, 2023 (JP) 2023-123380

(51) Int. Cl. H10P 14/20; H10D 62/60; H10D 62/85; H10D 62/854; H10P 14/24; H10P 52/00

(52) U.S. Cl. CPC H10P 14/3416; H10D 62/60; H10D 62/8503; H10D 62/854; H10P 14/24; H10P 52/00

(57) ABSTRACT

A Group III nitride semiconductor epitaxial wafer includes: a Group III nitride semiconductor substrate exhibiting n-type conductivity and having a carrier concentration of 10²⁰ cm⁻³ or more; and a Group III nitride semiconductor film including an epitaxial layer epitaxially grown on the Group III nitride semiconductor substrate, wherein the Group III nitride semiconductor film has a thickness of 1 μm or more and 30 μm or less; and wherein the Group III nitride semiconductor substrate has an off-angle of 0.38 degrees or more and 0.6 degrees or less between a normal to a surface of the Group III nitride semiconductor substrate and a c-axis of the Group III nitride semiconductor substrate, and the Group III nitride semiconductor film is provided on the surface of the Group III nitride semiconductor substrate.

### CROSS REFERENCE TO RELATED APPLICATION

This application claims priorities of Japanese Patent Application No. 2023-123380 filed on Jul. 28, 2023 and PCT Application No. PCT/JP2024/005738 filed on Feb. 19, 2024, the contents of which are incorporated herein by reference.

### BACKGROUND

### 1. Field of the Invention

The present disclosure relates to a Group III nitride semiconductor epitaxial wafer having a Group III nitride semiconductor substrate and a Group III nitride semiconductor film epitaxially grown thereon, and to a device using the Group III nitride semiconductor epitaxial wafer.

### 2. Description of the Related Art

Group III nitride semiconductors are used in fields such as optical devices such as semiconductor lasers and light-emitting diodes, as well as high-frequency or high-power electronic devices. These semiconductors have attracted particular attention in recent years because they are expected to reduce switching losses during power conversion compared to silicon-based devices. In order to fabricate high-frequency or high-power electronic devices, it is necessary to fabricate the devices on high-quality Group III nitride substrates that can suppress the occurrence of crystal defects in the device layer.

Methods for producing Group III nitride crystals include, for example, hydride vapor phase epitaxy (hereinafter, also referred to as HVPE), ammonothermal, sodium flux, and oxide vapor phase epitaxy (hereinafter, also referred to as OVPE).

In the HVPE method, which is most often used as a substrate manufacturing method, hydrogen halide gas is introduced onto a single Group III source material to generate a halide gas, and the generated Group III element halide gas is used as a source gas for crystal growth. For example, in the case of growing gallium nitride crystals, HCl gas is introduced into Ga metal to produce gallium chloride (e.g., GaCl₂) gas, and the gallium chloride-containing gas is used as a Group III source, thereby achieving high- speed growth at 1 mm/h or more. In the HVPE method, it is known that Group III nitride crystals with N-type conductivity can be obtained mainly by adding silicon element to the Group III nitride crystals.

In the OVPE method, an oxide source gas is used to add a high concentration of oxygen element to a Group III nitride crystal to produce the crystal (see, e.g., WO2015053341A1). In this method, a Group III oxide gas reacts with a nitrogen-containing gas to produce a Group III nitride crystal. The substrate obtained by this method has a low dislocation density of the order of 10⁴ cm⁻², and the OVPE method is one means for obtaining a high-quality Group III nitride crystal.

Group III nitride crystals produced by the above-described methods can be processed to obtain Group III nitride substrates. Devices can be fabricated by forming epitaxial films of Group III nitride semiconductors on these substrates. It is known that dislocations, among crystal defects of the substrate, are inherited by the epitaxial films produced. However, because dislocations are thought to be a cause of leakage during device operation, efforts have been made to develop methods to prevent inheritance of dislocations from the substrate to the epitaxial film (see, e.g., JP2010103353A).

In recent years, however, research has been progressing on reducing the dislocation density of the substrate itself using the above Group III nitride crystal production methods, such as the HVPE method, OVPE method, and sodium flux method. Currently, in many cases, by growing thick crystals, it is possible to obtain substrates with a dislocation density of the order to 1×10⁶ cm⁻² or less. In the crystal growth of thin films during device formation, it is possible to slightly reduce the dislocation density, but it is becoming more difficult to significantly reduce it compared to the substrate. Therefore, it is becoming unnecessary to adopt the method described in JP2010103353A.

In recent years, research has been conducted on the idea that leakage, particularly in vertical power devices, is caused by fluctuations in the surface of each device layer in the thickness direction during formation (see, e.g., I. C. Kizilyalli et al., Microelectron Reliab. 55, 1654 (2015)). It is believed that leakage occurs due to fluctuations in each device layer and the electrode formation surface, which cause localized electric field concentration. Therefore, this suggests that crystal growth of an epitaxial film with a flat surface may be necessary to reduce leakage in devices.

Vertical power devices generally have a structure in which current also flows through the substrate. Hence, in order to reduce the resistance during device operation, it is necessary to reduce the resistance of the substrate as well. Among the above methods for producing Group III nitride crystals, OVPE is capable of easily doping oxygen atoms, which act as donors in the Group III nitride crystal, at high concentrations, and is known as a method for producing low-resistance substrates.

The present inventors have developed a method for easily doping oxygen atoms at a high concentration to obtain gallium nitride crystals doped with oxygen atoms at a compositional level, with an oxygen concentration of 4.4×10²⁰ atoms ·cm⁻³ or higher. Among Group III nitride crystals, for example, the molecular density in gallium nitride crystals is 4.4×10²² cm⁻³. In gallium nitride, oxygen atoms are believed to be incorporated into the crystal by substituting for nitrogen atoms, and an oxygen concentration of 4.4×10²⁰ atoms·cm⁻³ may correspond to 1 atomic %, which can be regarded as the doping level at a compositional level.

In semiconductor crystals, impurities are added into the crystal to control the electrical properties, but generally the concentration of the impurities is at most about 10¹⁹ atoms·cm⁻³, and they are rarely added at a compositional level. The reason for this is that if impurities are added at a high concentration, segregation of the impurities can lead to a decrease in crystal quality and an increase in the generation of polycrystals, making it difficult to obtain a high-quality thick single crystal.

Also, there are very few examples of Group III nitride crystals, particularly those containing impurities at the compositional level, being used as substrates to form epitaxial films thereon. Furthermore, in crystals containing impurities at the compositional level, basic physical properties such as the lattice constant of the crystal deviate from their original values. On the other hand, epitaxial films do not contain impurities at the compositional level, and have physical properties relatively close to those of the original material.

For example, if the lattice constant difference between the epitaxial film and the underlying substrate is large, dislocations are introduced into the epitaxial film due to lattice relaxation, and the substrate may warp during epitaxial film formation. This results in a deterioration of the surface condition of the epitaxial film. In other words, it is generally difficult to maintain crystalline quality of the epitaxial film when forming the epitaxial film with a low impurity concentration on the substrate with an extremely high impurity concentration.

### SUMMARY

The present disclosure is intended to solve the above-mentioned problems, and one non-limiting and exemplary embodiments provides a Group III nitride semiconductor epitaxial wafer in which a Group III nitride semiconductor film with an extremely flat surface is formed on a Group III nitride semiconductor doped with a high concentration of impurities.

In one general aspect, the techniques disclosed here feature:
a Group III nitride semiconductor epitaxial wafer includes:
a Group III nitride semiconductor substrate exhibiting n-type conductivity and having a carrier concentration of 10²⁰ cm⁻³ or more; and
a Group III nitride semiconductor film including an epitaxial layer epitaxially grown on the Group III nitride semiconductor substrate,
wherein the Group III nitride semiconductor film has a thickness of 1 μm or more and 30 μm or less; and
wherein the Group III nitride semiconductor substrate has an off-angle of 0.38 degrees or more and 0.6 degrees or less between a normal to a surface of the Group III nitride semiconductor substrate and a c-axis of the Group III nitride semiconductor substrate, and
the Group III nitride semiconductor film is provided on the surface of the Group III nitride semiconductor substrate.

The Group III nitride semiconductor epitaxial wafer according to the present disclosure enables the formation of devices with reduced leakage and low operational loss.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view showing an example of a nitride semiconductor epitaxial wafer according to a first embodiment of the present invention;

FIGS. 2A to 2F show differential interference microscope images of the surfaces of gallium nitride films obtained using Group III nitride semiconductor substrates having different off-angles in Example;

FIGS. 3A to 3F show atomic force microscope (AFM) images at a field of view of 90 μm in Example;

FIGS. 4A to 4E show differential interference microscope images of the surfaces of gallium nitride films obtained using Group III nitride semiconductor substrates having different off-angles in Comparative Example;

FIGS. 5A to 5E show atomic force microscope (AFM) images at a field of view of 90 μm in Comparative Example; and

FIG. 6 is a diagram showing the relationship between surface roughness and substrate off-angle in Example and Comparative Example.

### DETAILED DESCRIPTION

A Group III nitride semiconductor epitaxial wafer according to a first aspect, includes:
a Group III nitride semiconductor substrate exhibiting n-type conductivity and having a carrier concentration of 10²⁰ cm⁻³ or more; and
a Group III nitride semiconductor film including an epitaxial layer epitaxially grown on the Group III nitride semiconductor substrate, wherein the Group III nitride semiconductor film has a thickness of 1 μm or more and 30 μm or less; and
wherein the Group III nitride semiconductor substrate has an off-angle of 0.38 degrees or more and 0.6 degrees or less between a normal to a surface of the Group III nitride semiconductor substrate and a c-axis of the Group III nitride semiconductor substrate, and
the Group III nitride semiconductor film is provided on the surface of the Group III nitride semiconductor substrate.

In the Group III nitride semiconductor epitaxial wafer according to a second aspect in addition to the first aspect, the surface of the Group III nitride semiconductor film may have a root mean square (RMS) roughness of 10 nm or less within a 50 μm square area.

In the Group III nitride semiconductor epitaxial wafer according to a third aspect in addition to the second aspect, the surface of the Group III nitride semiconductor film may have a root mean square (RMS) roughness of 5 nm or less within a 50 μm square area; and

the off-angle formed between a normal to the surface of the Group III nitride semiconductor substrate and a c-axis of the Group III nitride semiconductor substrate may be 0.4 degrees or more and 0.55 degrees or less.

In the Group III nitride semiconductor epitaxial wafer according to a fourth aspect in addition to any one of the first to third aspects, an n-type dopant element of the Group III nitride semiconductor substrate may be oxygen.

In the Group III nitride semiconductor epitaxial wafer according to a fifth aspect in addition to any one of the first to fourth aspects, a main Group III element of the Group III nitride semiconductor substrate may be gallium.

In the Group III nitride semiconductor epitaxial wafer according to a sixth aspect in addition to the fifth aspect, the Group III nitride semiconductor substrate may have an oxygen concentration of 4.4×10²⁰ atoms·cm⁻³ or more.

In the Group III nitride semiconductor epitaxial wafer according to a seventh aspect in addition to any one of the first to sixth aspects, the Group III nitride semiconductor film may include an epitaxial layer having a carrier concentration lower than that of the Group III nitride semiconductor substrate.

In the Group III nitride semiconductor epitaxial wafer according to an eighth aspect in addition to any one of the first to seventh aspects, the Group III nitride semiconductor film may include an epitaxial layer having a carrier concentration of 5×10¹⁶ cm⁻³ or less.

In the Group III nitride semiconductor epitaxial wafer according to a ninth aspect in addition to any one of the first to eighth aspects, the Group III nitride semiconductor film may have a thickness of 1 μm or more and 8 μm or less.

A device according to a tenth aspect includes the Group III nitride semiconductor epitaxial wafer according to any one of the first to ninth aspects.

A method for producing a Group III nitride semiconductor epitaxial wafer according to an eleventh aspect includes:
forming a Group III nitride semiconductor substrate exhibiting n-type conductivity and having a carrier concentration of 10²⁰ cm⁻³ or more by an OVPE method;
polishing a surface of the obtained Group III nitride semiconductor substrate to obtain a Group III nitride semiconductor substrate having a polished surface such that the Group III nitride semiconductor substrate has an off-angle of 0.38 degrees or more and 0.6 degrees or less between a normal of the polished surface and a c-axis of the Group III nitride semiconductor substrate; and
epitaxially growing a Group III nitride semiconductor film on the surface of the Group III nitride semiconductor substrate having an off-angle of 0.38 degrees or more and 0.6 degrees or less.

In the method for producing the Group III nitride semiconductor epitaxial wafer according to a twelfth aspect in addition to the eleventh aspect,

in the course of polishing the Group III nitride semiconductor substrate, the Group III nitride semiconductor substrate may be disposed such that the Group III nitride semiconductor substrate has an inclination of 0.38 degrees or more and 0.6 degrees or less between the normal to an imaginary polished surface and the c-axis of the Group III nitride semiconductor substrate, the imaginary polished surface is a flat surface obtained by polishing, and the surface of the Group III nitride semiconductor substrate is polished so as to be parallel to the imaginary polished surface, thereby obtaining a Group III nitride semiconductor substrate having the off-angle of 0.38 degrees or more and 0.6 degrees or less formed between the normal to the polished surface and the c-axis.

Hereinafter, a Group III nitride semiconductor epitaxial wafer and device according to an embodiment of the present disclosure will be described using examples. Note, however, that the present disclosure is not limited in any way by the use of numerical values or specific elements used in the following description.

### First Embodiment

### Group III Nitride Semiconductor Epitaxial Wafer

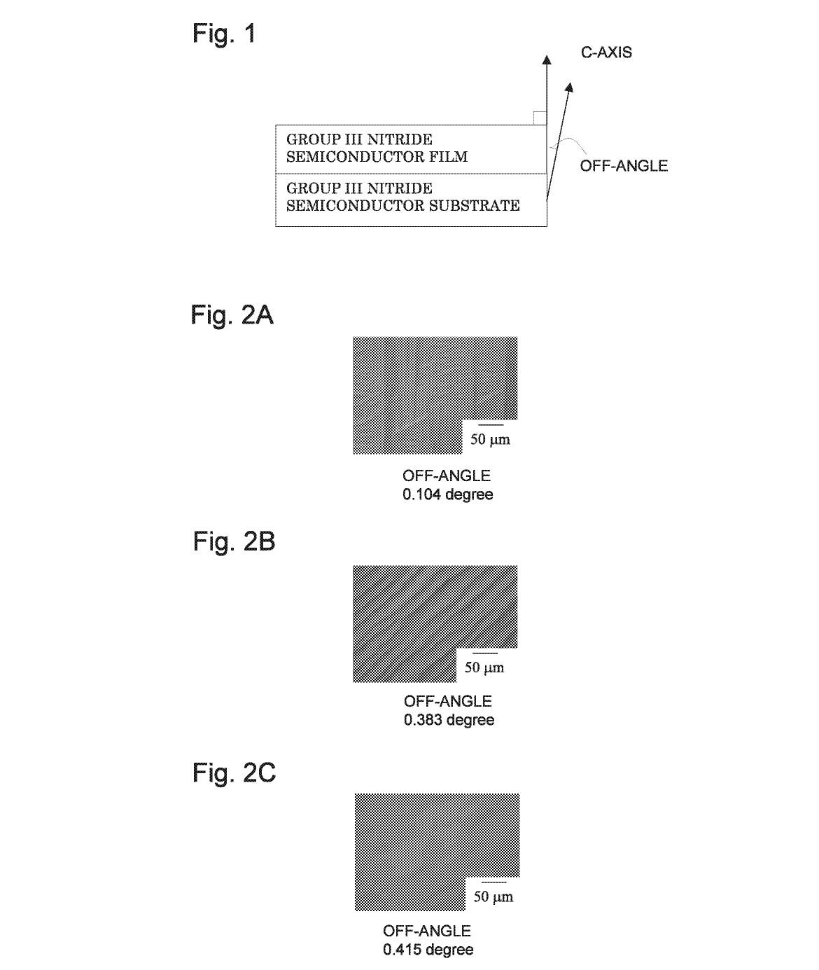

FIG. 1 is a schematic cross-sectional view showing an example of a nitride semiconductor epitaxial wafer according to a first embodiment.

A Group III nitride semiconductor epitaxial wafer according to the present disclosure includes at least two layers: a Group III nitride semiconductor substrate and a Group III nitride semiconductor film including an epitaxial layer epitaxially grown on the Group III nitride semiconductor substrate.

Each of the members constituting this Group III nitride semiconductor epitaxial wafer will be described below.

### Group III Nitride Semiconductor Substrate

In order to reduce the on-resistance during operation, the Group III nitride semiconductor substrate is preferably doped with an impurity that acts as an n-type dopant, exhibits n-type conductivity, and has a carrier concentration of 10²⁰ cm⁻³ or more.

As shown in FIG. 1, the normal to the surface of the Group III nitride semiconductor substrate is preferably tilted at an angle of 0.38 degrees or more and 0.6 degrees or less from the c-axis of the Group III nitride semiconductor crystal having a hexagonal wurtzite crystal structure, and more preferably at an angle of 0.4 degrees or more and 0.55 degrees or less. Hereinafter, this tilt angle may be simply referred to as the "off angle." This makes it easier to maintain the flatness of the surface when a Group III nitride semiconductor film including an epitaxial layer is formed on the Group III nitride semiconductor substrate.

The n-type dopant element of the Group III nitride semiconductor substrate may include at least one element selected from the group consisting of silicon, germanium, and oxygen.

The n-type dopant element of the Group III nitride semiconductor substrate, for example, may include oxygen. It possible to easily add oxygen to the Group III nitride semiconductor crystal, particularly when the Group III nitride semiconductor crystal used for the substrate is produced by OVPE and the Group III nitride semiconductor substrate includes oxygen as an n-type dopant element.

When oxygen is the main n-type dopant element in a Group III nitride semiconductor substrate may include oxygen, for example, at a compositional level of 4.4×10²⁰ atoms·cm⁻³ or more, which makes it easy to achieve a carrier concentration of 10²⁰ cm⁻³ or more in the Group III nitride semiconductor substrate.

### Group III Nitride Semiconductor Film

A Group III nitride semiconductor film includes an epitaxial layer epitaxially grown on a Group III nitride semiconductor substrate. Its electrical characteristics are determined on the basis of the performance required for the device, and are not limited to specific carrier concentrations or polarities such as p-type or n-type. However, in order to reduce leakage current when a device is formed, the surface flatness may be, for example, such that the root mean square (RMS) roughness measured in a randomly selected 50 μm square area from the surface is 10 nm or less, and further 5 nm or less. The epitaxial layer constituting the Group III nitride semiconductor film may be a single layer, or may have a structure of two or more layers.

The Group III nitride semiconductor film may include at least one epitaxial layer having a carrier concentration of 5×10¹⁶ cm⁻³ or less. By combining a Group III nitride semiconductor film including an epitaxial layer having a low carrier concentration with a substrate having a high carrier concentration, it becomes easy to implement a device with low resistance and high breakdown voltage, which has not been implemented so far.

The Group III nitride semiconductor film has a thickness of 1 μm or more and 30 μm or less.

The thickness of the Group III nitride semiconductor film may be 1 μm or more. If the Group III nitride semiconductor film is thinner than 1 μm, a sufficiently stable surface is not formed when forming an epitaxial layer on the substrate, and the surface is likely to become rough depending on the flatness of the substrate.

The thickness of the Group III nitride semiconductor film may be 30 μm or less. When it is 30 μm or less, it may be easy to maintain the flatness of the surface due to the influence of lattice mismatch. Further, when it is 30 μm or less, it is easy to maintain the flatness of the epitaxial layer, and since the substrate of the present disclosure has a very high carrier concentration and is doped with a large amount of impurities, it is possible to maintain the flatness of the surface although the lattice constant of the crystal deviates from that of a pure Group III nitride semiconductor crystal.

The thickness of the Group III nitride semiconductor film may be 1 μm or more and 8 μm or less. When the thickness is 1 μm or more and 8 μm or less, a film having a sufficiently stable surface can be formed, and sufficient flatness can be maintained even when the lattice mismatch between the substrate and the epitaxial layer is large.

This Group III nitride semiconductor epitaxial wafer has a root mean square (RMS) roughness of 10 nm or less when measured over a 50 μm square area, and when the Group III nitride semiconductor epitaxial wafer is used in electronic devices, it can implement devices with low resistance during operation and low leakage current.

### Method for Manufacturing Group III Nitride Semiconductor Epitaxial Wafer

The method for manufacturing a Group III nitride semiconductor epitaxial wafer according to the first embodiment includes the following steps.
(1) A Group III nitride semiconductor substrate exhibiting n-type conductivity and having a carrier concentration of 10²⁰ cm⁻³ or more is formed by, for example, OVPE. Note that the manufacturing method of a Group III nitride semiconductor substrate by OVPE may be carried out under ordinary conditions.
(2) The surface of the obtained Group III nitride semiconductor substrate is polished to obtain a Group III nitride semiconductor substrate having a surface in which the off-angle between the normal and the c-axis of the Group III nitride semiconductor substrate is 0.38 degrees or more and 0.6 degrees or less. The process of obtaining a Group III nitride semiconductor substrate having a surface in which the off-angle is 0.38 degrees or more and 0.6 degrees or less will be described later.
(3) A Group III nitride semiconductor film is epitaxially grown on a surface of a Group III nitride semiconductor substrate having an off-angle of 0.38 degrees or more and 0.6 degrees or less. The Group III nitride semiconductor film may be epitaxially grown by, for example, metal-organic vapor phase epitaxy (MOVPE). Note that the epitaxial growth method is not limited to MOVPE.

In this manner, a Group III nitride semiconductor epitaxial wafer can be obtained.

### Process for Obtaining Group III Nitride Semiconductor Substrate Having Surface with Off-Angle of 0.38 to 0.6 Degrees

At the step of polishing a Group III nitride semiconductor substrate, the Group III nitride semiconductor substrate is disposed so that the Group III nitride semiconductor substrate has an inclination of 0.38 degrees or more and 0.6 degrees or less between the normal to an imaginary polished surface and the c-axis of the Group III nitride semiconductor substrate. The imaginary polished surface is a flat surface obtained by polishing. The imaginary polished surface may be a horizontal plane. Alternatively, the imaginary polished surface is not limited to a horizontal plane and may be a vertical plane.

In a typical Group III nitride semiconductor substrate, the c-plane, to which the c-axis is the normal, appears on the surface. Therefore, when the imaginary polished surface is horizontal, the c-plane, which is the surface of the disposed Group III nitride semiconductor substrate, is inclined with respect to the horizontal. Therefore, the Group III nitride semiconductor substrate may be disposed on a jig whose surface normal is inclined at an angle of 0.38 degrees to 0.6 degrees with respect to the vertical direction.

Thereafter, the surface of the Group III nitride semiconductor substrate is polished so as to be parallel to the polished surface, thereby obtaining a Group III nitride semiconductor substrate having an off-angle of 0.38 degrees or more and 0.6 degrees or less between the normal and the c-axis of the Group III nitride semiconductor substrate.

### Electronic Devices

The Group III nitride semiconductor epitaxial wafer may be used in electronic devices, thereby implementing devices with low resistance and low leakage current during operation.

### Examples

In the examples, a gallium nitride substrate manufactured by OVPE was used as the Group III nitride semiconductor substrate, and a gallium nitride film, which is a Group III nitride semiconductor film, was formed by metal organic vapor phase epitaxy (MOVPE).

The gallium nitride substrate used had an oxygen concentration of 1×10²¹ atoms·cm⁻³, an n-type carrier concentration of 2×10²⁰ cm⁻³, and a thickness of 400 μm. The off-angle was varied from 0.383 degrees to 0.584 degrees. The gallium nitride film was doped with silicon, was n-type, had a carrier concentration of 2×10¹⁶ cm⁻³, and had a thickness of 8 μm. After the gallium nitride film was formed, the surface condition was evaluated using an atomic force microscope (AFM), and the RMS value of a 50 μm square area was measured.

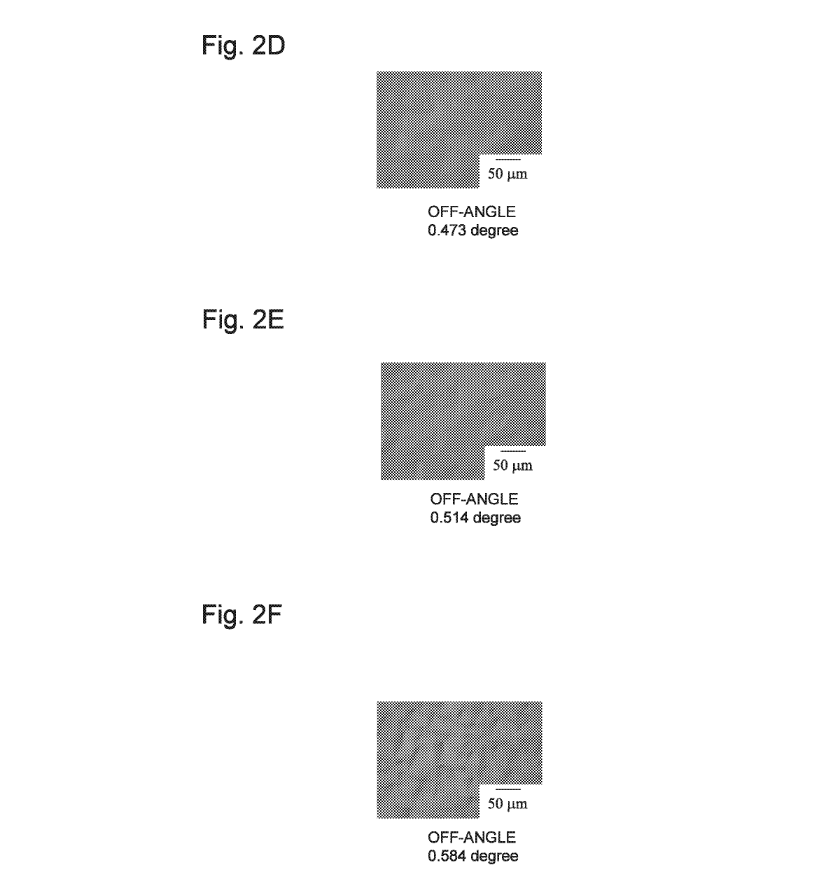

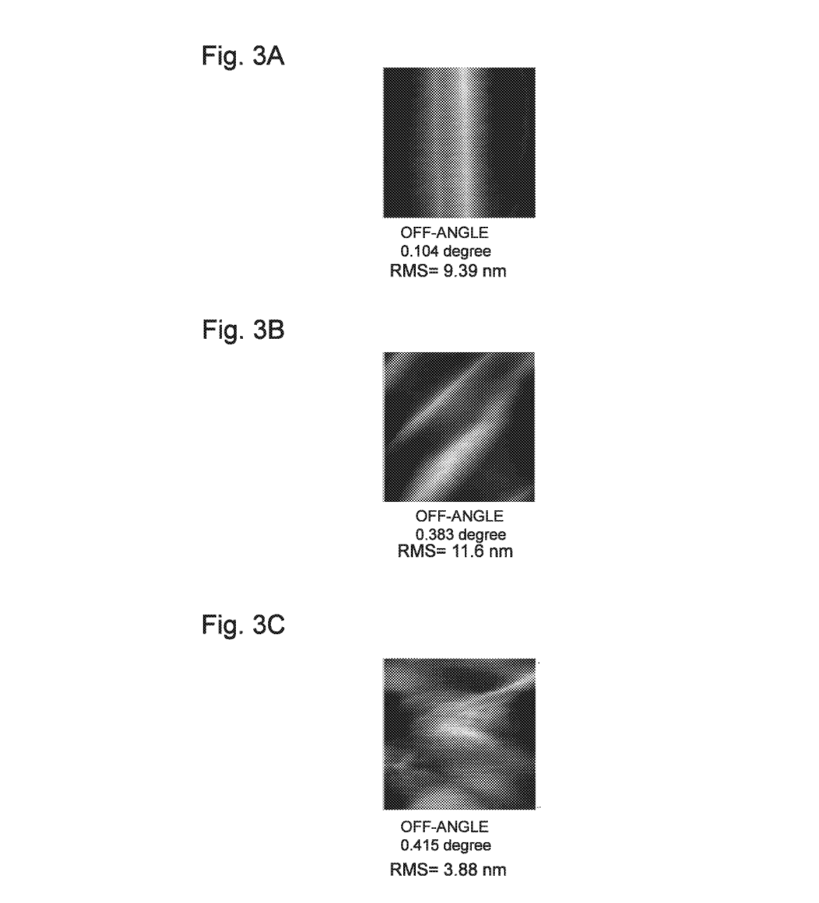

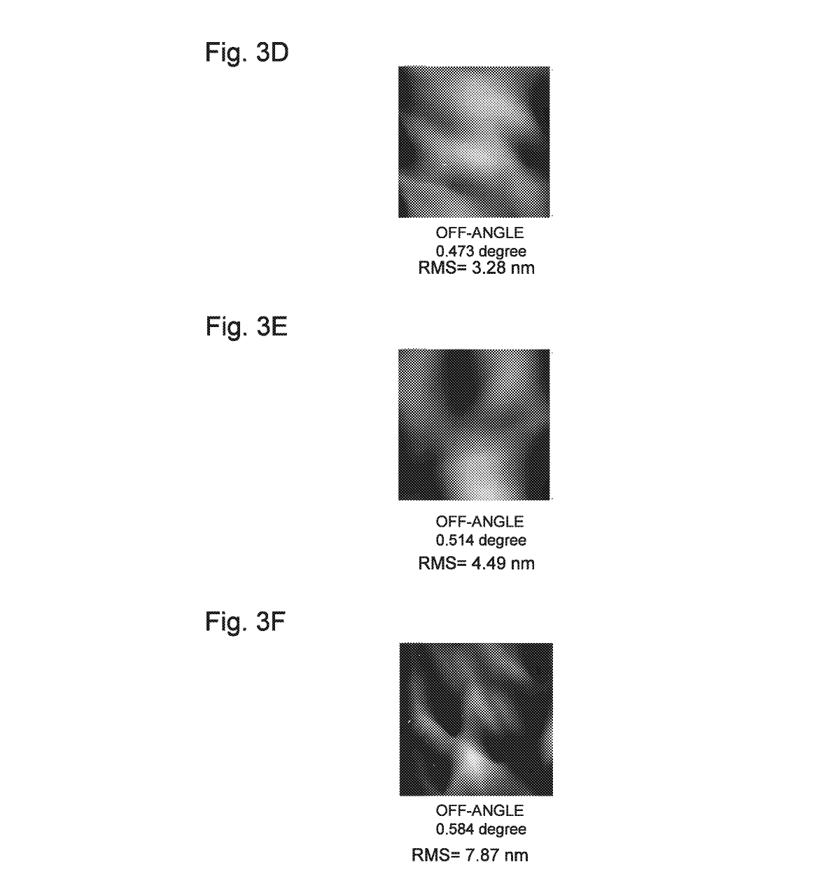

FIGS. 2A-2F show differential interference microscope images of the surfaces of gallium nitride films obtained using Group III nitride semiconductor substrates having different off-angles in the Examples, and FIGS. 3A-3F show atomic force microscope (AFM) images with a field of view of 90 μm in the Examples.

The differential interference microscope images in FIGS. 2A-2F show that the surface is flat when the off angle is 0.415 degrees (FIG. 2C), 0.473 degrees (FIG. 2D), and 0.514 degrees (FIG. 2E). The atomic force microscope images in FIGS. 3A-3F also show that the contrast between light and dark is relatively small and the surface is flat when the off angle is 0.415 degrees (FIG. 3C), 0.473 degrees (FIG. 3D), and 0.514 degrees (FIG. 3E).

Considering FIGS. 2A-2F and 3A-3F, it was confirmed that when the off-angle is 0.4 degrees or more and 0.5 degrees or less, the surface of the epitaxial film grown is relatively flat in the differential interference microscope images, and furthermore, from the atomic force microscope (AFM) images, it was confirmed to be possible to grow the epitaxial film having a flat film with RMS suppressed to 5 nm or less.

### Comparative Examples

In Comparative Examples, a gallium nitride substrate manufactured by the HVPE method was used as the Group III nitride semiconductor substrate, and a gallium nitride film was epitaxially grown on the Group III nitride semiconductor substrate by the MOVPE method in the same manner as in the Examples.

The gallium nitride substrate used was n-type, had a carrier concentration of 2×10¹⁸ cm⁻³, and was 400 μm thick. The off-angle was varied from 0.355 degrees to 0.611 degrees. The gallium nitride film was n-type, had a carrier concentration of 2×10¹⁶ cm⁻³, and had a thickness of 8 μm, with silicon introduced as a dopant element. After the gallium nitride film was grown, the surface condition was evaluated with an atomic force microscope (AFM), and the RMS value of a 50 μm square area was measured, as in the Examples.

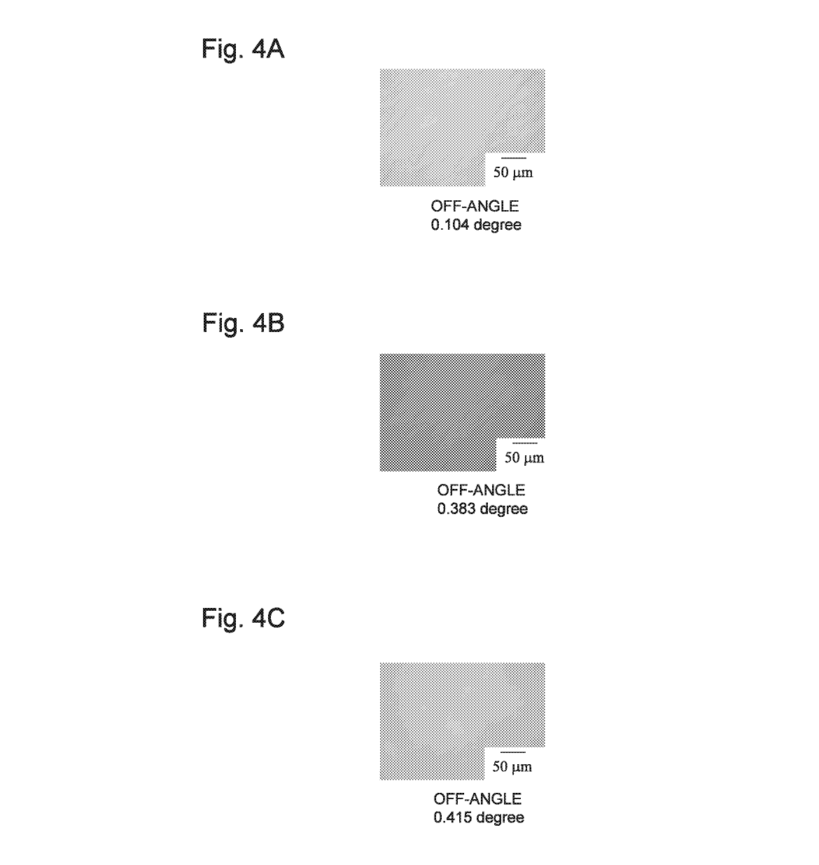

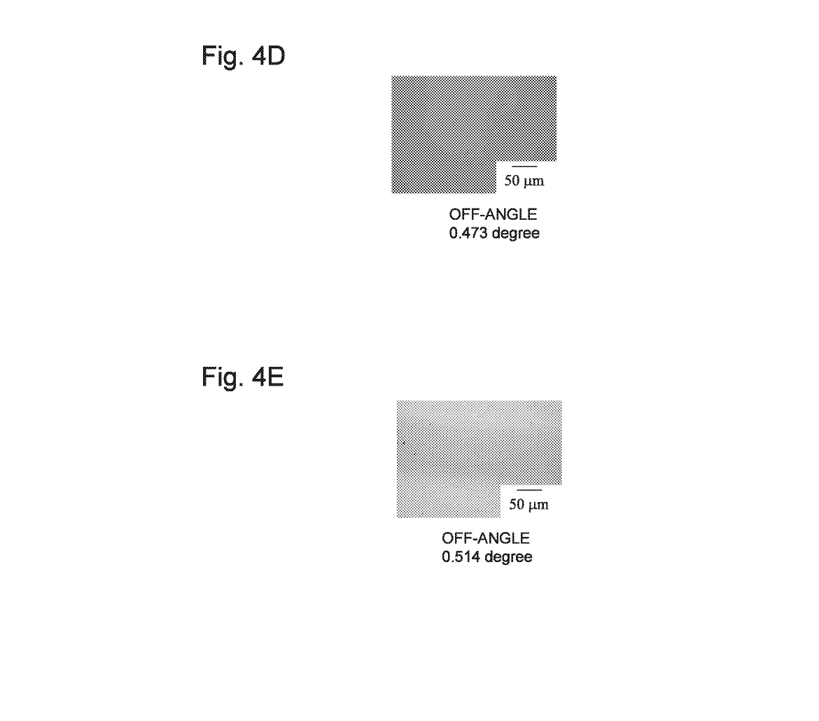

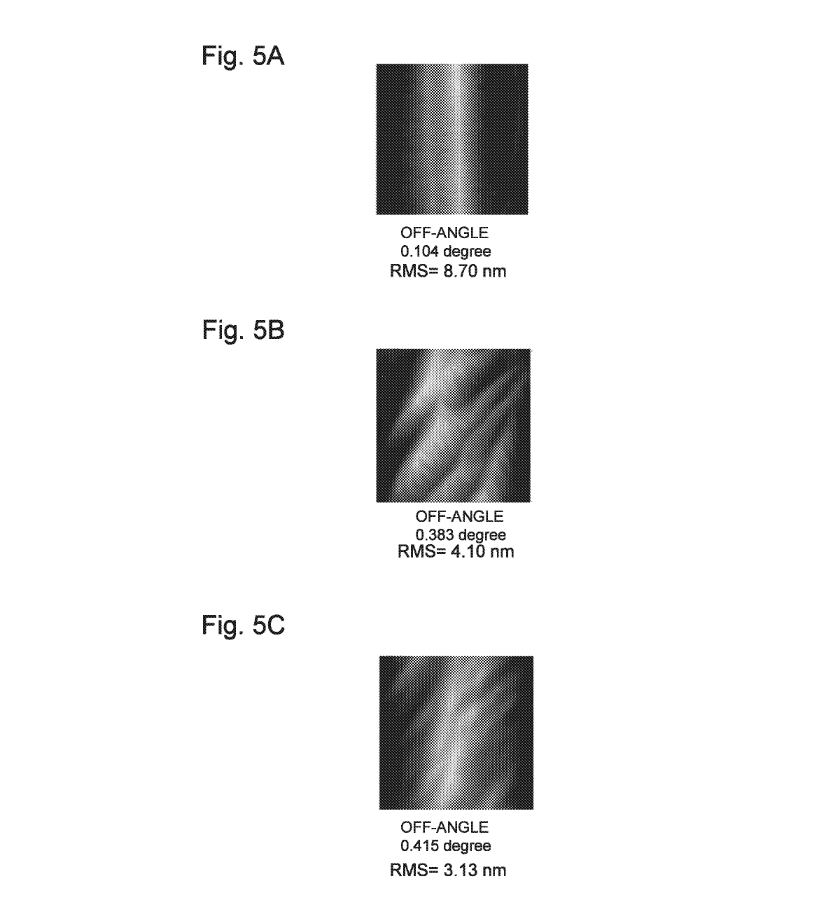

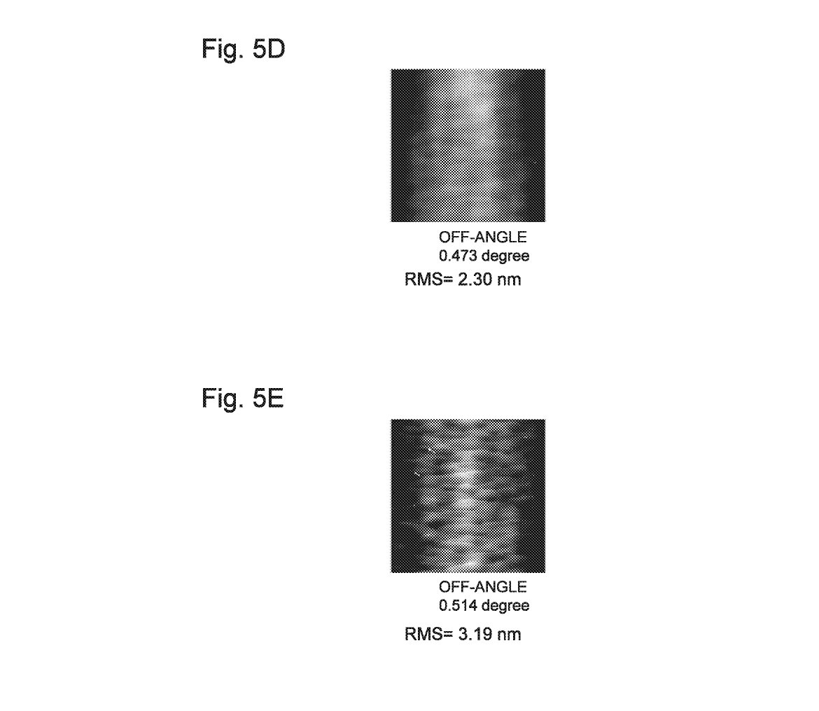

FIGS. 4A-4E show differential interference microscope images of the surfaces of gallium nitride films obtained using Group III nitride semiconductor substrates having different off-angles in the Comparative Examples, and FIGS. 5A-5E show atomic force microscope (AFM) images with a field of view of 90 μm in the Comparative Examples.

Considering FIGS. 4A-4E and 5A-5E, it can be seen that the Group III nitride film grown on the substrate with a low impurity concentration is relatively flat in the differential interference microscope images of the surface at any off-angle, and furthermore, it was confirmed from the atomic force microscope images (AFM images) that a flat film with an RMS suppressed to 5 nm or less can be formed over a wide range of off-angles of 0.4 degrees or more.

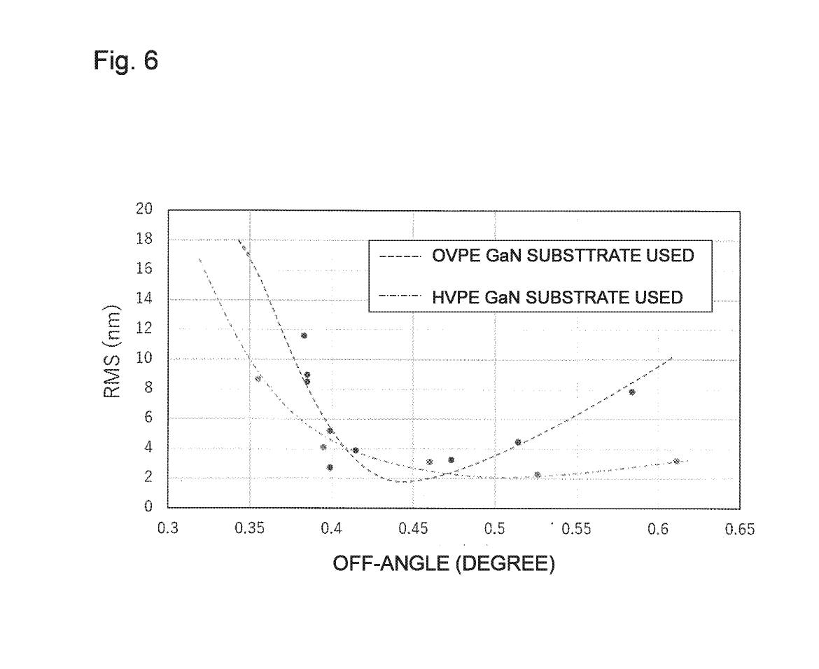

FIG. 6 is a diagram showing the relationship between surface roughness and the off-angle of the substrate in the examples and comparative examples. As shown in

FIG. 6, in the Comparative Example, it was confirmed that an off-angle of 0.4 degrees or more is sufficient to achieve an RMS value of 5 nm or less. On the other hand, in the Examples, it was confirmed that an RMS value of 10 nm or less was achieved when the off-angle was in the range of 0.38 to 0.6 degrees, and that in order to achieve an RMS value of 5 nm or less, the off-angle needed to be limited to a narrow range of 0.4 to 0.55 degrees.

It was confirmed that in substrates with high impurity concentrations, the off-angle has a significant effect on improving flatness in a limited narrow region.

As set forth hereinabove, the Group III nitride semiconductor epitaxial wafer according to the present disclosure enables the formation of a flat Group III nitride semiconductor epitaxial film, which is expected to reduce leakage current in low on-resistance electronic devices and improve reliability.

What is claimed is:

1. A Group III nitride semiconductor epitaxial wafer comprising:
a Group III nitride semiconductor substrate exhibiting n-type conductivity and having a carrier concentration of 10²⁰ cm⁻³ or more; and
a Group III nitride semiconductor film including an epitaxial layer epitaxially grown on the Group III nitride semiconductor substrate,
wherein the Group III nitride semiconductor film has a thickness of 1 μm or more and 30 μm or less; and
wherein the Group III nitride semiconductor substrate has an off-angle of 0.38 degrees or more and 0.6 degrees or less between a normal to a surface of the Group III nitride semiconductor substrate and a c-axis of the Group III nitride semiconductor substrate, and
the Group III nitride semiconductor film is provided on the surface of the Group III nitride semiconductor substrate.

2. The Group III nitride semiconductor epitaxial wafer according to claim 1, wherein the surface of the Group III nitride semiconductor film has a root mean square (RMS) roughness of 10 nm or less within a 50 μm square area.

3. The Group III nitride semiconductor epitaxial wafer according to claim 2, wherein:
the surface of the Group III nitride semiconductor film has a root mean square (RMS) roughness of 5 nm or less within a 50 μm square area; and
the off-angle formed between a normal to the surface of the Group III nitride semiconductor substrate and a c-axis of the Group III nitride semiconductor substrate is 0.4 degrees or more and 0.55 degrees or less.

4. The Group III nitride semiconductor epitaxial wafer according to claim 1, wherein an n-type dopant element of the Group III nitride semiconductor substrate is oxygen.

5. The Group III nitride semiconductor epitaxial wafer according to claim 1, wherein a main Group III element of the Group III nitride semiconductor substrate is gallium.

6. The Group III nitride semiconductor epitaxial wafer according to claim 5, wherein the Group III nitride semiconductor substrate has an oxygen concentration of 4.4×10²⁰ atoms·cm⁻³ or more.

7. The Group III nitride semiconductor epitaxial wafer according to claim 1, wherein the Group III nitride semiconductor film includes an epitaxial layer having a carrier concentration lower than that of the Group III nitride semiconductor substrate.

8. The Group III nitride semiconductor epitaxial wafer according to claim 1, wherein the Group III nitride semiconductor film includes an epitaxial layer having a carrier concentration of 5×10¹⁶ cm⁻³ or less.

9. The Group III nitride semiconductor epitaxial wafer according to claim 1, wherein the Group III nitride semiconductor film has a thickness of 1 μm or more and 8 μm or less.

10. A device comprising the Group III nitride semiconductor epitaxial wafer according to claim 1.

11. A method for producing a Group III nitride semiconductor epitaxial wafer, comprising:
forming a Group III nitride semiconductor substrate exhibiting n-type conductivity and having a carrier concentration of 10²⁰ cm⁻³ or more by an OVPE method;
polishing a surface of the obtained Group III nitride semiconductor substrate to obtain a Group III nitride semiconductor substrate having a polished surface such that the Group III nitride semiconductor substrate has an off-angle of 0.38 degrees or more and 0.6 degrees or less between a normal of the polished surface and a c-axis of the Group III nitride semiconductor substrate; and
epitaxially growing a Group III nitride semiconductor film on the surface of the Group III nitride semiconductor substrate having an off-angle of 0.38 degrees or more and 0.6 degrees or less.

12. The method for producing a Group III nitride semiconductor epitaxial wafer according to claim 11,
wherein in the course of polishing the Group III nitride semiconductor substrate, the Group III nitride semiconductor substrate is disposed such that the Group III nitride semiconductor substrate has an inclination of 0.38 degrees or more and 0.6 degrees or less between the normal to an imaginary polished surface and the c-axis of the Group III nitride semiconductor substrate, the imaginary polished surface is a flat surface obtained by polishing, and the surface of the Group III nitride semiconductor substrate is polished so as to be parallel to the imaginary polished surface, thereby obtaining a Group III nitride semiconductor substrate having the off-angle of 0.38 degrees or more and 0.6 degrees or less formed between the normal to the polished surface and the c-axis.
